(19) United States
(12) Patent Application Publication
(10) Pub. No.: US 2026/0254345 A1
(43) Pub. Date: Aug. 27, 2026

(54) POWER MANAGEMENT CIRCUIT

(71) Applicant: SK hynix Inc., Gyeonggi-do (KR)

(72) Inventor: Myeong Woo KIM, Gyeonggi-do (KR)

(21) Appl. No.: 19/207,372

(22) Filed: May 14, 2025

(30) Foreign Application Priority Data
Feb. 27, 2025 (KR) 10-2025-0025829

(51) Int. Cl. H02M 1/088; H02M 1/00; H02M 3/158

(52) U.S. Cl. CPC H02M 1/088; H02M 1/0003; H02M 3/158

(57) ABSTRACT

A power management circuit includes a voltage conversion circuit, a multi-mode control circuit, and a drive control circuit. The voltage conversion circuit generates an operating voltage according to an input voltage and a plurality of drive control signals. The multi-mode control circuit divides the operating voltage to generate a feedback voltage, generates an operating voltage detection signal according to the feedback voltage and a first reference voltage, varies a frequency of a ramp voltage to match one of a plurality of operation modes selected according to the operating voltage detection signal and a second reference voltage, and generates a comparison signal according to the operating voltage detection signal and the ramp voltage. The drive control circuit generates the plurality of drive control signals according to the comparison signal.

### CROSS-REFERENCES TO RELATED APPLICATION

The present application claims priority under 35 U.S.C. § 119(a) to Korean application number 10-2025-0025829 filed on Feb. 27, 2025, which is incorporated herein by reference in its entirety.

### BACKGROUND

### 1. Technical Field

Various embodiments of the present disclosure generally relate to a semiconductor circuit, and more particularly, to a power management circuit.

### 2. Related Art

All electronic devices, including memory solutions, wearable devices, and IoT (Internet of Things) devices, essentially require a power management circuit between a power source (e.g., battery) and functional circuits to provide the desired voltage and current from the power source.

Electronic devices such as memory solutions, wearable devices, and IoT devices are becoming increasingly smaller, and the power capacity of power sources such as batteries is also limited, so it is essential to make power management circuits low-power and small in order to operate electronic devices at maximum efficiency for a long time.

The power management circuit is designed to operate in either pulse width modulation (PWM) mode or pulse frequency modulation (PFM) mode. It is necessary to selectively apply the pulse width modulation mode and the pulse frequency modulation mode according to the operating conditions of the functional circuit that uses the power generated by the power management circuit.

### SUMMARY

In an embodiment of the present disclosure, a power management may include a voltage conversion circuit, a multi-mode control circuit, and a drive control circuit. The voltage conversion circuit may be configured to generate an operating voltage according to an input voltage and a plurality of drive control signals. The multi-mode control circuit may be configured to divide the operating voltage to generate a feedback voltage, generate an operating voltage detection signal according to the feedback voltage and a first reference voltage, vary a frequency of a ramp voltage to match one of a plurality of operation modes selected according to the operating voltage detection signal and a second reference voltage, and generate a comparison signal according to the operating voltage detection signal and the ramp voltage. The drive control circuit may be configured to generate the plurality of drive control signals according to the comparison signal.

In an embodiment of the present disclosure, a power management may include a voltage conversion circuit, a multi-mode control circuit, and a drive control circuit. The voltage conversion circuit may be configured to generate an operating voltage according to an input voltage and a plurality of drive control signals. The drive control circuit may be configured to generate the plurality of drive control signals according to a comparison signal. The voltage conversion circuit, the multi-mode control circuit, and the drive control circuit may form a single loop. The multi-mode control circuit may be configured to select an operation mode from among a plurality of operation modes according to the operating voltage, generate a ramp voltage with a variable frequency according to the selected operation mode, and adjust a level of the comparison signal according to the operating voltage and the ramp voltage.

In an embodiment of the present disclosure, a power management may include a voltage conversion circuit, an amplification circuit, a mode selection circuit, a ramp voltage generation circuit, a first comparator, and a drive control circuit. The voltage conversion circuit may be configured to generate an operating voltage according to an input voltage and a plurality of drive control signals. The amplification circuit may be configured to generate an operating voltage detection signal according to a feedback voltage and a first reference voltage, the feedback voltage being generated by dividing the operating voltage. The mode selection circuit may be configured to select one of a pulse width modulation mode and a pulse frequency modulation mode according to the operating voltage detection signal and a second reference voltage, and generate a frequency control voltage adjusted according to the selected mode. The ramp voltage generation circuit may be configured to vary a frequency of a ramp voltage according to the frequency control voltage and a third reference voltage. The first comparator may be configured to generate a comparison signal according to the operating voltage detection signal and the ramp voltage. The drive control circuit may be configured to generate the plurality of drive control signals according to the comparison signal.

### BRIEF DESCRIPTION OF THE DRAWINGS

FIG. 1 is a diagram illustrating a configuration of a power management circuit according to an embodiment of the present disclosure.

FIG. 2 is a diagram illustrating a detailed configuration of a voltage conversion circuit of FIG. 1, according to an embodiment of the present disclosure.

FIG. 3 is a diagram illustrating a detailed configuration of a multi-mode control circuit of FIG. 1, according to an embodiment of the present disclosure.

FIG. 4 is a diagram illustrating a detailed configuration of a mode selection circuit of FIG. 3, according to an embodiment of the present disclosure.

FIG. 5 is a diagram illustrating a detailed configuration of a ramp voltage generation circuit of FIG. 3, according to an embodiment of the present disclosure.

FIG. 6 is a diagram illustrating a detailed configuration of a drive control circuit of FIG. 1, according to an embodiment of the present disclosure.

FIG. 7 is a diagram for describing a control method for each of multiple modes of a power management circuit according to an embodiment of the present disclosure.

FIG. 8 is a diagram illustrating changes in detection voltage and switching frequency according to variations in load current of a power management circuit according to an embodiment of the present disclosure.

FIG. 9 is a flowchart for describing an operation of a power management circuit according to an embodiment of the present disclosure.

### DETAILED DESCRIPTION

Various embodiments of the present disclosure enable single-loop-based multi-mode control, which makes circuit design easier, reduces the circuit area, and increases operation efficiency by maintaining stable output during mode switching.

Hereinafter, embodiments of the present disclosure will be described in more detail with reference to the accompanying drawings.

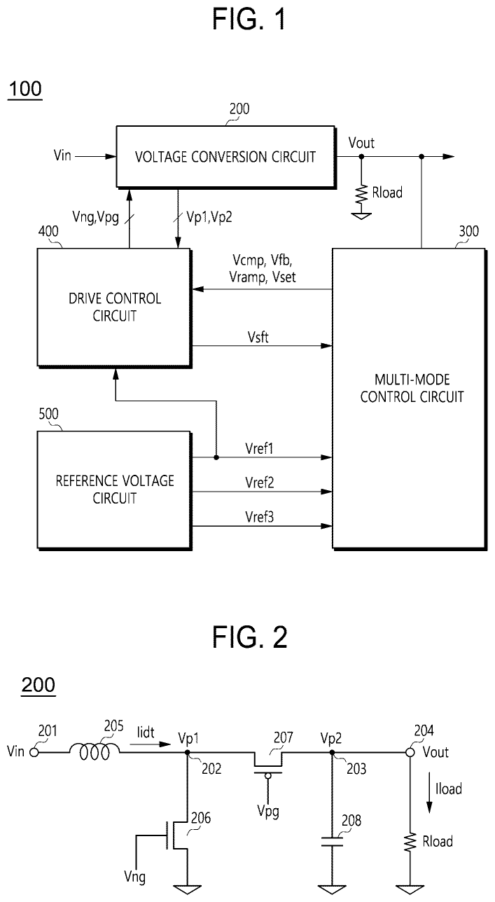

FIG. 1 is a diagram illustrating a configuration of a power management circuit 100 according to an embodiment of the present disclosure.

Referring to FIG. 1, the power management circuit 100 may include a voltage conversion circuit 200, a multi-mode control circuit 300, a drive control circuit 400, and a reference voltage circuit 500.

The voltage conversion circuit 200 may receive an input voltage Vin and a plurality of drive control signals Vng, Vpg, and output an operating voltage Vout. The voltage conversion circuit 200 may generate the operating voltage Vout by adjusting the power transmitted from the input voltage Vin according to the plurality of drive control signals Vng, Vpg. Voltages Vp1, Vp2 of internal nodes of the voltage conversion circuit 200 may be output and provided to the drive control circuit 400. The operating voltage Vout may be applied to a load Rload. The load Rload models a functional circuit that is coupled to the power management circuit 100 and operates according to the operating voltage Vout. Hereinafter, among the plurality of drive control signals Vng, Vpg, “Vng” is referred to as a first drive control signal, and “Vpg” is referred to as a second drive control signal.

The multi-mode control circuit 300 may receive the operating voltage Vout, a plurality of reference voltages Vref1, Vref2, Vref3 and a soft start signal Vsft and output a comparison signal Vcmp, a feedback voltage Vfb, a ramp voltage Vramp and a ramp voltage detection signal Vset.

The multi-mode control circuit 300 may select an operation mode from a plurality of operation modes according to the operating voltage Vout and adjust a level of the comparison signal Vcmp according to the selected operation mode. The plurality of operation modes may include a first operation mode based on a pulse width modulation method and a second operation mode based on a pulse frequency modulation method. The first operation mode may include a first sub-mode and a second sub-mode. The first sub-mode is a continuous conduction mode (CCM) based on pulse width modulation, and the second sub-mode is a discontinuous conduction mode (DCM) based on pulse width modulation.

The multi-mode control circuit 300 may generate an operating voltage detection signal according to the feedback voltage, generated by dividing the operating voltage Vout, and the first reference voltage Vref1, and vary the frequency of the ramp voltage Vramp to match one of the plurality of operation modes selected according to the operating voltage detection signal and the second reference voltage Vref2. Additionally, the multi-mode control circuit 300 may generate the comparison signal Vcmp according to the operating voltage detection signal and the ramp voltage Vramp.

The drive control circuit 400 may receive the comparison signal Vcmp, the feedback voltage Vfb, the ramp voltage Vramp, the ramp voltage detection signal Vset, the first reference voltage Vref1, and the voltages Vp1, Vp2 of the internal nodes of the voltage conversion circuit 200, and output the plurality of drive control signals Vng, Vpg and the soft start signal Vsft.

The reference voltage circuit 500 may generate the plurality of reference voltages Vref1, Vref2, Vref3. The reference voltage circuit 500 may include a band gap reference circuit. The plurality of reference voltages Vref1, Vref2, Vref3 may be generated at different levels. The levels of the plurality of reference voltages Vref1, Vref2, Vref3 may be set differently depending on the circuit design method.

Among the plurality of reference voltages Vref1, Vref2, Vref3, ‘Vref1’ serves as an output reference voltage, which may be used as a criterion to determine whether the operating voltage Vout has reached a target level. ‘Vref2’ serves as an operation mode reference voltage, which may be used as a criterion to determine whether to switch between the first operation mode and the second operation mode. ‘Vref3’ serves as a ramp reference voltage, which may be used as a criterion for detecting a peak value of the ramp voltage Vramp. Hereinafter, ‘Vref1’ is referred to as a first reference voltage, ‘Vref2’ as a second reference voltage, and ‘Vref3’ as a third reference voltage.

FIG. 2 is a diagram illustrating a detailed configuration of the voltage conversion circuit 200 of FIG. 1, according to an embodiment of the present disclosure.

Referring to FIG. 2, the voltage conversion circuit 200 may include an inductor 205, a first switch 206, a second switch 207, and a capacitor 208.

The inductor 205 may be coupled between an input terminal 201 and a first node 202. The first switch 206 may be coupled between the first node 202 and a ground terminal. The first switch 206 may be configured using an NMOS transistor. The first switch 206 may be turned on according to a first logic level, for example, a logic high level of the first drive control signal Vng, and turned off according to a second logic level, for example, a logic low level of the first drive control signal Vng. The second switch 207 may be coupled between the first node 202 and a second node 203. The second switch 207 may be configured using a PMOS transistor. The second switch 207 may be turned on according to a logic low level at the second drive control signal Vpg and turned off according to a logic high level at the second drive control signal Vpg. The capacitor 208 may be coupled between the second node 203 and the ground terminal. For example, the first switch 206 may include an NMOS transistor, and the second switch 207 may include a PMOS transistor.

As the second drive control signal Vpg at a low level is input, inductor current Iidt, which flows through the inductor 205, is charged to the capacitor 208 through the second switch 207, and voltage applied to both ends of the capacitor 208 may be output as the operating voltage Vout through an output terminal 204 coupled to the second node 203. The current flowing into the load Rload may be referred to as load current Iload, and the amount of the load current Iload may vary depending on a value of the load Rload. As mentioned earlier, the load Rload models a functional circuit that operates by receiving the operating voltage Vout.

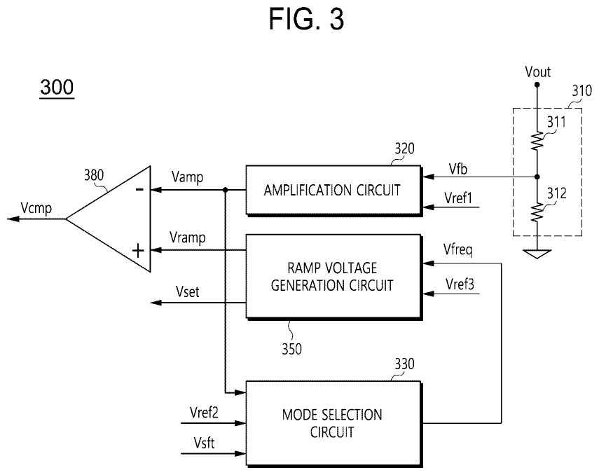

FIG. 3 is a diagram illustrating a detailed configuration of the multi-mode control circuit 300 of FIG. 1, according to an embodiment of the present disclosure.

The multi-mode control circuit 300 may include a divider circuit 310, an amplification circuit 320, a mode selection circuit 330, a ramp voltage generation circuit 350, and a first comparator 380.

The divider circuit 310 may generate the feedback voltage Vfb by dividing the operating voltage Vout to match the resistance ratio of distribution resistors 311, 312. For example, when the resistance ratio of the distribution resistors 311, 312 is designed to be 1:1, the divider circuit 310 may generate the feedback voltage Vfb at a level equivalent to half of the operating voltage Vout.

The amplification circuit 320 may receive the feedback voltage Vfb and the first reference voltage Vref1 and output an operating voltage detection signal Vamp. The amplification circuit 320 may output a signal, which amplifies a voltage level difference between the feedback voltage Vfb and the first reference voltage Vref1, as the operating voltage detection signal Vamp.

The mode selection circuit 330 may receive the operating voltage detection signal Vamp, the second reference voltage Vref2, and the soft start signal Vsft and output a frequency control voltage Vfreq. The mode selection circuit 330 may select one of a pulse width modulation mode and a pulse frequency modulation mode according to the operating voltage detection signal Vamp and the second reference voltage Vref2, and adjust a level of the frequency control voltage Vfreq to match the selected mode.

The ramp voltage generation circuit 350 may receive the frequency control voltage Vfreq and the third reference voltage Vref3 and output the ramp voltage Vramp and the ramp voltage detection signal Vset. The ramp voltage generation circuit 350 may vary the frequency of the ramp voltage Vramp according to the frequency control voltage Vfreq and the third reference voltage Vref3.

The first comparator 380 may receive the operating voltage detection signal Vamp and the ramp voltage Vramp and output the comparison signal Vcmp. The first comparator 380 may output a result of comparing voltage levels of the ramp voltage Vramp and the operating voltage detection signal Vamp as the comparison signal Vcmp.

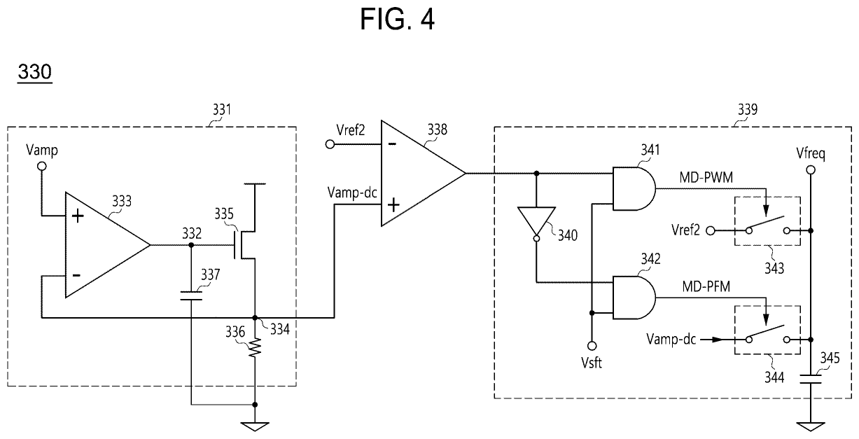

FIG. 4 is a diagram illustrating a detailed configuration of the mode selection circuit 330 of FIG. 3, according to an embodiment of the present disclosure.

Referring to FIG. 4, the mode selection circuit 330 may include an input buffer 331, a second comparator 338, and a voltage selection circuit 339.

The input buffer 331 may receive the operating voltage detection signal Vamp and output an operating voltage average detection signal Vamp-dc. The input buffer 331 may operate as a low pass filter and output a signal that removes high frequency components of the operating voltage detection signal Vamp as the operating voltage average detection signal Vamp-dc. The input buffer 331 may include a differential amplifier 333, a transistor 335, a resistor 336, and a capacitor 337. When the differential amplifier 333 receives the operating voltage detection signal Vamp at a first input terminal ‘+’, a second input terminal ‘−’ is coupled to a second node 334, and an output terminal is coupled to a first node 332. The transistor 335 is coupled between a power terminal and the second node 334 and is driven by a voltage level of the first node 332. The resistor 336 is coupled between the second node 334 and a ground terminal. The capacitor 337 is coupled between the first node 332 and the ground terminal. Voltage induced across the resistor 336 is output as the operating voltage average detection signal Vamp-dc through the second node 334. For example, the transistor 335 may include an NMOS transistor.

The second comparator 338 may output a result of comparing a voltage level of the operating voltage average detection signal Vamp-dc with a voltage level of the second reference voltage Vref2.

The voltage selection circuit 339 may output the second reference voltage Vref2 as the frequency control voltage Vfreq when an output of the second comparator 338 is a first logic level, for example, a logic high level, and output the operating voltage average detection signal Vamp-dc as the frequency control voltage Vfreq when the output of the second comparator 338 is a second logic level, for example, a logic low level. The voltage selection circuit 339 may include a first to third logic gates 340, 341, 342, a first switch 343, a second switch 344, and a capacitor 345.

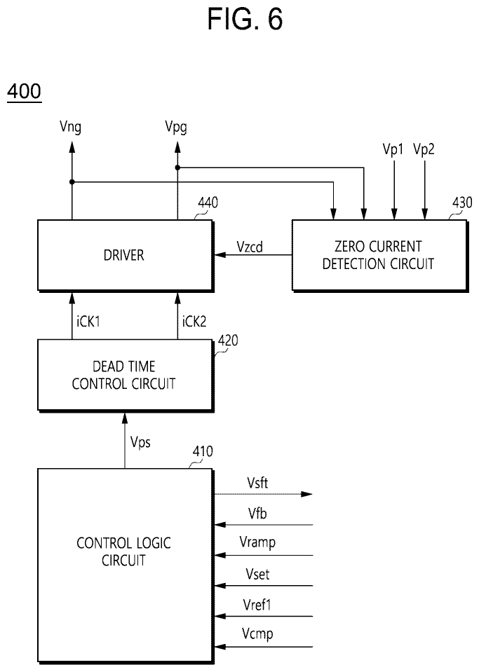

The first logic gate 340 may invert and output the output of the second comparator 338. The second logic gate 341 may output a result from performing an AND operation on the output of the second comparator 338 and the soft start signal Vsft as a first operation mode signal MD-PWM. The soft start signal Vsft is a signal for determining whether the power management circuit 100 has entered a steady-state operation, which will be described with reference to FIG. 6. The first operation mode signal MD-PWM may be used as a signal to operate the power management circuit 100 in a first operation mode, i.e., pulse width modulation mode, according to an embodiment of the present disclosure. The third logic gate 342 may output a result from performing an AND operation on an inverted output of the first logic gate 340 and the soft start signal Vsft as a second operation mode signal MD-PFM. The second operation mode signal MD-PFM may be used as a signal to operate the power management circuit 100 in a second operation mode, i.e., pulse frequency modulation mode, according to an embodiment of the present disclosure. The first switch 343 may output the second reference voltage Vref2 as the frequency control voltage Vfreq when the first operation mode signal MD-PWM is at a logic high level. The second switch 344 may output the operating voltage average detection signal Vamp-dc as the frequency control voltage Vfreq when the second operation mode signal MD-PFM is at a logic high level. For example, when the soft start signal Vsft and the output of the second comparator 338 are at a logic high level, the first operation mode signal MD-PWM is at a logic high level and the second operation mode signal MD-PFM is at a logic low level, so the second reference voltage Vref2 is output as the frequency control voltage Vfreq and the power management circuit 100 may operate in the pulse width modulation mode. When the soft start signal Vsft is at a logic high level and the output of the second comparator 338 is at a logic low level, the first operation mode signal MD-PWM is at a logic low level and the second operation mode signal MD-PFM is at a logic high level, so the operating voltage average detection signal Vamp-dc is output as the frequency control voltage Vfreq and the power management circuit 100 may operate in the pulse frequency modulation mode. The capacitor 345 is coupled to the first switch 343 and the second switch 344 at one end and to the ground terminal at the other end, and may be used to stabilize the frequency control voltage Vfreq.

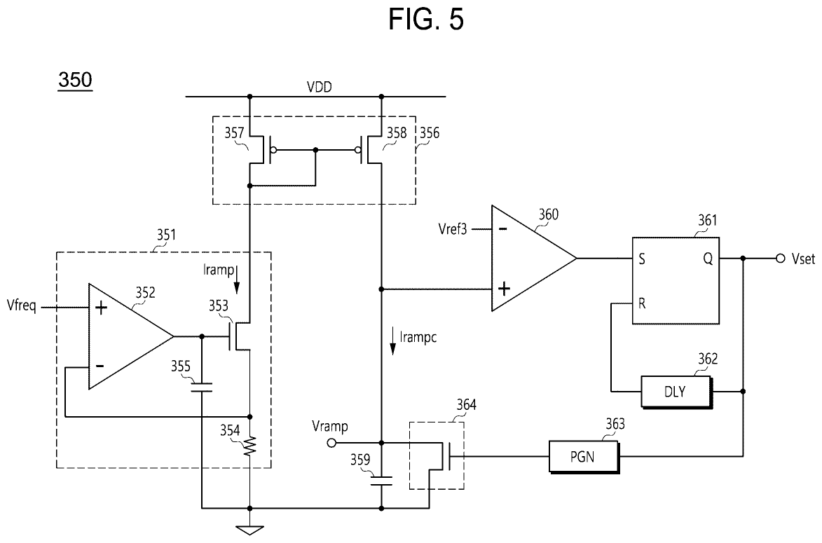

FIG. 5 is a diagram illustrating a detailed configuration of the ramp voltage generation circuit 350 of FIG. 3, according to an embodiment of the present disclosure.

Referring to FIG. 5, the ramp voltage generation circuit 350 may include an input buffer 351, a current mirror 356, a capacitor 359, a third comparator 360, a latch 361, a delay circuit (DLY) 362, a pulse generation circuit (PGN) 363, and a switch 364.

The input buffer 351 may adjust a first ramp current Iramp according to a voltage level obtained by removing high frequency components from the frequency control voltage Vfreq. The input buffer 351 may include a differential amplifier 352, a transistor 353, a resistor 354, and a capacitor 355 and may be configured similarly to the input buffer 331 of FIG. 4. The current mirror 356 may mirror the first ramp current Iramp to generate a second ramp current Irampc. The current mirror 356 may include a first transistor 357 and a second transistor 358. A drain terminal of the first transistor 357 may be coupled to a gate terminal of the first transistor 357 and a gate terminal of the second transistor 358. The first ramp current Iramp flowing through the first transistor 357 may be mirrored through the second transistor 358 to generate the second ramp current Irampc. The capacitor 359 may charge the second ramp current Irampc to generate the ramp voltage Vramp. The third comparator 360 may output a result of comparing the ramp voltage Vramp with the third reference voltage Vref3. The latch 361 may be an SR latch. The latch 361 may set the ramp voltage detection signal Vset to a logic high level according to an output of the third comparator 360. The delay circuit 362 may delay a logic level of the ramp voltage detection signal Vset by a set time and then input it to a reset terminal R of the latch 361. The ramp voltage detection signal Vset may be transitioned to a logic low level by the delay operation of the delay circuit 362. The pulse generation circuit 363 may generate a single pulse according to a rising edge of the ramp voltage detection signal Vset. The switch 364 may transition the ramp voltage Vramp to a logic low level by discharging the capacitor 359 according to the single pulse generated by the pulse generation circuit 363. By repeatedly charging and discharging the capacitor 359 in the manner described above, the ramp voltage Vramp may be made to have a sawtooth-shaped waveform. For example, each of the transistor 353 and the switch 364 may include an NMOS transistor. Each of the first transistor 357 and the second transistor 358 may include a PMOS transistor.

FIG. 6 is a diagram illustrating a detailed configuration of the drive control circuit 400 of FIG. 1, according to an embodiment of the present disclosure.

Referring to FIG. 6, the drive control circuit 400 may include a control logic circuit 410, a dead time control circuit 420, a zero current detection circuit 430, and a driver 440.

The control logic circuit 410 may receive the feedback voltage Vfb, the ramp voltage Vramp, the ramp voltage detection signal Vset, the first reference voltage Vref1, and the comparison signal Vcmp and output the soft start signal Vsft and a drive pulse signal Vps. The control logic circuit 410 may output the soft start signal Vsft at a logic low level when the feedback voltage Vfb is lower than the first reference voltage Vref1, and output the soft start signal Vsft at a logic high level when the feedback voltage Vfb is equal to or greater than the first reference voltage Vref1. The soft start signal Vsft is a signal for determining whether the power management circuit 100 has entered a steady-state operation. The control logic circuit 410 compares the feedback voltage Vfb with the first reference voltage Vref1, and outputs the soft start signal Vsft at a logic low level to prevent excessive current increase until the power management circuit 100 enters a steady-state operation. Specifically, when the feedback voltage Vfb is lower than the first reference voltage Vref1, the soft start signal Vsft remains at a logic low level. When the feedback voltage Vfb is equal to or greater than the first reference voltage Vref1, the control logic circuit 410 determines that the power management circuit 100 has entered a state capable of normal operation and may transition the soft start signal Vsft to a logic high level. The control logic circuit 410 may generate the drive pulse signal Vps based on a logic combination of the ramp voltage Vramp, the ramp voltage detection signal Vset, and the comparison signal Vcmp.

The dead time control circuit 420 may receive the drive pulse signal Vps and output a first clock signal iCK1 and a second clock signal iCK2. The dead time control circuit 420 is a circuit that may generate a pair of clock signals that do not overlap with each other, and ensure that the first clock signal iCK1 and the second clock signal iCK2 do not have an overlapping interval.

The zero current detection circuit 430 may receive the voltages Vp1, Vp2 of the internal nodes of the voltage conversion circuit 200, the first drive control signal Vng, and the second drive control signal Vpg and output a zero current detection signal Vzcd. The zero current detection circuit 430 is a circuit for determining whether the current flowing through the second switch 207 of the voltage conversion circuit 200 is a forward current. If the current flowing through the second switch 207 is a reverse current, the efficiency of the power management circuit 100 is reduced. Therefore, the zero current detection circuit 430 may generate a zero current detection signal Vzcd at a logic high level when it detects, through the voltages Vp1, Vp2 of the internal nodes of the voltage conversion circuit 200, the first drive control signal Vng, and the second drive control signal Vpg, that the forward current flowing through the second switch 207 is approaching zero.

The driver 440 may receive the first clock signal iCK1, the second clock signal iCK2, and the zero current detection signal Vzcd and output the first drive control signal Vng and the second drive control signal Vpg. The driver 440 may generate the first drive control signal Vng that strengthens driving force to appropriately drive the first switch 206 of the voltage conversion circuit 200 according to the first clock signal iCK1 and the second clock signal iCK2. The driver 440 keeps the second drive control signal Vpg at a logic high level when the zero current detection signal Vzcd is at a logic high level, and keeps the second drive control signal Vpg at a logic low level when the zero current detection signal Vzcd is at a logic low level.

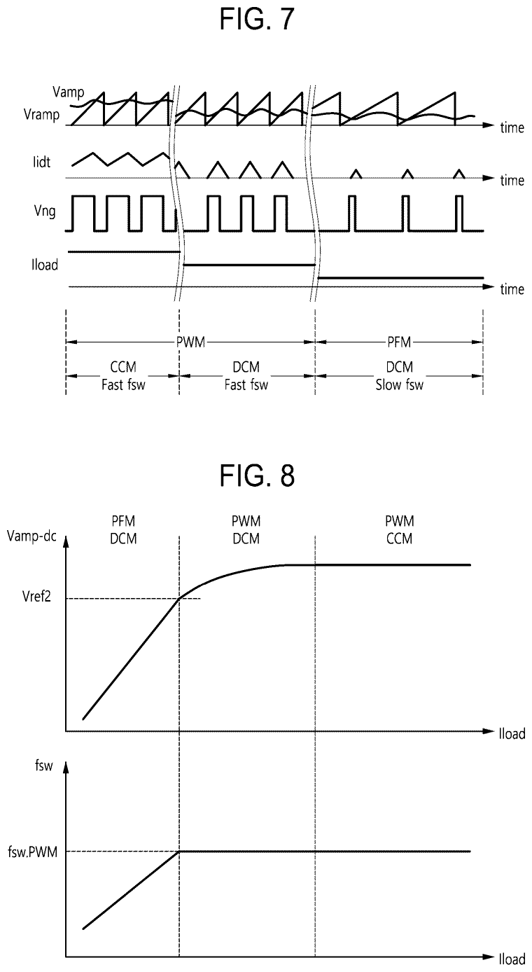

FIG. 7 is a diagram for describing a control method for each of multiple modes of a power management circuit according to an embodiment of the present disclosure, and FIG. 8 is a diagram illustrating changes in detection voltage and switching frequency according to variations in load current of a power management circuit according to an embodiment of the present disclosure.

Referring to FIG. 4 and FIG. 7, when a voltage level of the operating voltage detection signal Vamp is close to the maximum value of the ramp voltage Vramp, that is, when a difference between a voltage level of the operating voltage average detection signal Vamp-dc and the second reference voltage Vref2 is large, the power management circuit 100 operates in the first sub-mode of the first operation mode. The first sub-mode is a continuous conduction mode based on pulse width modulation, and a switching frequency fsw is high (corresponding to PWM CCM Fast fsw). The switching frequency may represent the switching frequency of the first drive control signal Vng.

As the load current Iload decreases compared to the first sub-mode of the first operation mode, the voltage level of the operating voltage detection signal Vamp also decreases, so the operation mode is switched by the operation of the mode selection circuit 330 described in FIG. 4. Therefore, the power management circuit 100 operates in the second sub-mode of the first operation mode. The second sub-mode is a discontinuous conduction mode based on pulse width modulation, and the switching frequency fsw is high (corresponding to PWM DCM Fast fsw).

If the voltage level of the operating voltage detection signal Vamp decreases and the voltage level of the operating voltage average detection signal Vamp-dc is less than the second reference voltage Vref2 as the load current Iload decreases further compared to the second sub-mode of the first operation mode, the operation mode is switched again by the operation of the mode selection circuit 330 described in FIG. 4. Therefore, the power management circuit 100 operates in the second operation mode. The second operation mode is a discontinuous conduction mode based on pulse frequency modulation, in which the switching frequency fsw is decreased (corresponding to PFM DCM Slow fsw).

As shown in FIG. 8, the voltage level of the operating voltage average detection signal Vamp-dc increases as the load current Iload increases. In addition, the voltage level of the operating voltage average detection signal Vamp-dc decreases as the load current Iload decreases.

The power management circuit 100 operates in the discontinuous conduction mode based on pulse frequency modulation (corresponding to PFM DCM) when the voltage level of the operating voltage average detection signal Vamp-dc is lower than the second reference voltage Vref2, and controls the first drive control signal Vng and the second drive control signal Vpg at a low switching frequency fsw.

The power management circuit 100 operates in the discontinuous conduction mode based on pulse width modulation (corresponding to PWM DCM) when the voltage level of the operating voltage average detection signal Vamp-dc becomes equal to or greater than the second reference voltage Vref2, and controls the first drive control signal Vng and the second drive control signal Vpg at a high switching frequency fsw.

The power management circuit 100 operates in the continuous conduction mode based on pulse width modulation (corresponding to PWM CCM) as the voltage level of the operating voltage average detection signal Vamp-dc rises above a threshold, and controls the first drive control signal Vng and the second drive control signal Vpg at a high switching frequency fsw.

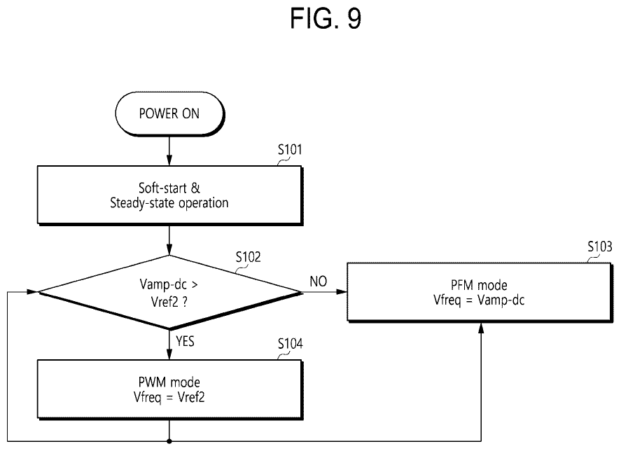

FIG. 9 is a flowchart for describing an operation of the power management circuit 100 according to an embodiment of the present disclosure.

Referring to FIG. 9, in operation S101, after the power management circuit 100 is powered on, the soft start signal Vsft is generated at a logic low level to perform a soft start operation. As the feedback voltage Vfb rises to be equal to or greater than the first reference voltage Vref1, the soft start signal Vsft transitions to a logic high level, and a steady-state operation is performed.

In operation S102, after entering the steady-state operation through the operation S101, it is determined whether the voltage level of the operating voltage average detection signal Vamp-dc is higher than the second reference voltage Vref2.

In operation S103, when the voltage level of the operating voltage average detection signal Vamp-dc is not higher than the second reference voltage Vref2 (i.e., “NO” in the operation S102), the power management circuit operates in the second operation mode (PFM) by setting the operating voltage average detection signal Vamp-dc as the frequency control voltage Vfreq.

In operation S104, when the voltage level of the operating voltage average detection signal Vamp-dc is higher than the second reference voltage Vref2 (i.e., “YES” in the operation S102), the power management circuit operates in the first operation mode (PWM) by setting the second reference voltage Vref2 as the frequency control voltage Vfreq.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope. Furthermore, the embodiments may be combined to form additional embodiments.

What is claimed is:

1. A power management circuit comprising:
a voltage conversion circuit configured to generate an operating voltage according to an input voltage and a plurality of drive control signals;
a multi-mode control circuit configured to
divide the operating voltage to generate a feedback voltage,
generate an operating voltage detection signal according to the feedback voltage and a first reference voltage,
vary a frequency of a ramp voltage to match one of a plurality of operation modes selected according to the operating voltage detection signal and a second reference voltage, and
generate a comparison signal according to the operating voltage detection signal and the ramp voltage; and
a drive control circuit configured to generate the plurality of drive control signals according to the comparison signal.

2. The power management circuit of claim 1, wherein the voltage conversion circuit comprises:
an inductor coupled between an input terminal of the voltage conversion circuit and a first node;
a first switch coupled between the first node and a ground terminal and driven according to a first drive control signal among the plurality of drive control signals; and
a second switch coupled between the first node and an output terminal of the voltage conversion circuit and driven according to a second drive control signal among the plurality of drive control signals.

3. The power management circuit of claim 1, wherein the plurality of operation modes include a first operation mode based on a pulse width modulation method and a second operation mode based on a pulse frequency modulation method.

4. The power management circuit of claim 3, wherein the first operation mode includes a first sub-mode and a second sub-mode, and wherein the first sub-mode is a continuous conduction mode based on the pulse width modulation method, and the second sub-mode is a discontinuous conduction mode based on the pulse width modulation method.

5. The power management circuit of claim 1, wherein the multi-mode control circuit comprises:
an amplification circuit configured to generate an operating voltage detection signal according to the feedback voltage and the first reference voltage;
a mode selection circuit configured to generate a frequency control voltage according to the operating voltage detection signal and the second reference voltage;
a ramp voltage generation circuit configured to generate the ramp voltage according to the frequency control voltage and a third reference voltage; and
a first comparator configured to generate the comparison signal according to the operating voltage detection signal and the ramp voltage.

6. The power management circuit of claim 5, wherein the mode selection circuit comprises:
an input buffer configured to remove high frequency components of the operating voltage detection signal to generate an operating voltage average detection signal;
a second comparator configured to compare the operating voltage average detection signal with the second reference voltage; and
a voltage selection circuit configured to:
output the second reference voltage as the frequency control voltage when an output of the second comparator is at a first logic level, and
output the operating voltage average detection signal as the frequency control voltage when the output of the second comparator is at a second logic level.

7. The power management circuit of claim 5, wherein the ramp voltage generation circuit comprises:
an input buffer configured to adjust a first ramp current according to a voltage level obtained by removing high frequency components from the frequency control voltage;
a current mirror configured to mirror the first ramp current to generate a second ramp current; and
a capacitor configured to be charged by the second ramp current to generate the ramp voltage.

8. The power management circuit of claim 7, further comprising:
a third comparator configured to compare the ramp voltage with the third reference voltage; and
a switch configured to be coupled to the capacitor and configured to discharge the ramp voltage according to an output of the third comparator.

9. The power management circuit of claim 1, wherein the drive control circuit comprises:
a control logic circuit configured to generate a drive pulse signal with variable frequency and pulse width according to the feedback voltage, the ramp voltage, the comparison signal, and the first reference voltage;
a dead time control circuit configured to generate clock signals having phases non-overlapping with each other, according to the drive pulse signal;
a driver configured to generate the plurality of drive control signals according to a zero current detection signal and the clock signals; and
a zero current detection circuit configured to generate the zero current detection signal according to the plurality of drive control signals and voltages of internal nodes of the voltage conversion circuit.

10. A power management circuit comprising:
a voltage conversion circuit configured to generate an operating voltage according to an input voltage and a plurality of drive control signals;
a multi-mode control circuit; and
a drive control circuit configured to generate the plurality of drive control signals according to a comparison signal,
wherein the voltage conversion circuit, the multi-mode control circuit, and the drive control circuit form a single loop, and
wherein the multi-mode control circuit is configured to: select an operation mode from among a plurality of operation modes according to the operating voltage, generate a ramp voltage with a variable frequency according to the selected operation mode, and adjust a level of the comparison signal according to the operating voltage and the ramp voltage.

11. The power management circuit of claim 1, wherein the voltage conversion circuit comprises:
an inductor coupled between an input terminal of the voltage conversion circuit and a first node;
a first switch coupled between the first node and a ground terminal and driven according to a first drive control signal among the plurality of drive control signals; and
a second switch coupled between the first node and an output terminal of the voltage conversion circuit and driven according to a second drive control signal among the plurality of drive control signals.

12. The power management circuit of claim 10, wherein the drive control circuit comprises:
a control logic circuit configured to generate a drive pulse signal with variable frequency and pulse width according to the comparison signal;
a dead time control circuit configured to generate clock signals having phases non-overlapping with each other according to the drive pulse signal;
a driver configured to generate the plurality of drive control signals according to a zero current detection signal and the clock signals; and
a zero current detection circuit configured to generate the zero current detection signal according to the plurality of drive control signals and voltages of internal nodes of the voltage conversion circuit.

13. The power management circuit of claim 10, wherein the plurality of operation modes include a first operation mode based on a pulse width modulation method and a second operation mode based on a pulse frequency modulation method.

14. The power management circuit of claim 13, wherein the first operation mode includes a first sub-mode and a second sub-mode, and wherein the first sub-mode is a continuous conduction mode based on the pulse width modulation method, and the second sub-mode is a discontinuous conduction mode based on the pulse width modulation method.

15. The power management circuit of claim 10, wherein the multi-mode control circuit is configured to:
divide the operating voltage to generate a feedback voltage;
generate an operating voltage detection signal according to the feedback voltage and a first reference voltage; and
vary a frequency of the ramp voltage according to the operating voltage detection signal and a second reference voltage.

16. A power management circuit comprising:
a voltage conversion circuit configured to generate an operating voltage according to an input voltage and a plurality of drive control signals;
an amplification circuit configured to generate an operating voltage detection signal according to a feedback voltage and a first reference voltage, wherein the feedback voltage is generated by dividing the operating voltage;
a mode selection circuit configured to select one of a pulse width modulation mode and a pulse frequency modulation mode according to the operating voltage detection signal and a second reference voltage, and generate a frequency control voltage adjusted according to the selected mode;
a ramp voltage generation circuit configured to vary a frequency of a ramp voltage according to the frequency control voltage and a third reference voltage;
a first comparator configured to generate a comparison signal according to the operating voltage detection signal and the ramp voltage; and
a drive control circuit configured to generate the plurality of drive control signals according to the comparison signal.

17. The power management circuit of claim 16, wherein the mode selection circuit comprises:
an input buffer configured to remove high frequency components of the operating voltage detection signal to generate an operating voltage average detection signal;
a second comparator configured to compare the operating voltage average detection signal with the second reference voltage; and
a voltage selection circuit configured to:
output the second reference voltage as the frequency control voltage when an output of the second comparator is at a first logic level, and
output the operating voltage average detection signal as the frequency control voltage when the output of the second comparator is at a second logic level.

18. The power management circuit of claim 16, wherein the ramp voltage generation circuit comprises:
an input buffer configured to adjust a first ramp current according to a voltage level obtained by removing high frequency components from the frequency control voltage;
a current mirror configured to mirror the first ramp current to generate a second ramp current; and
a capacitor configured to be charged by the second ramp current to generate the ramp voltage.

19. The power management circuit of claim 18, further comprising:
a third comparator configured to compare the ramp voltage with the third reference voltage; and
a switch configured to be coupled to the capacitor and configured to discharge the ramp voltage according to an output of the third comparator.
